(19) United States
(12) Patent Application Publication
(10) Pub. No.: US 2005/0029662 A1
(43) Pub. Date: Feb. 10, 2005

(54) Semiconductor production method

(76) Inventors: Hiroshi Nakano, Chiyoda-ku (JP); Takeyuki Itabashi, Chiyoda-ku (JP); Haruo Akahoshi, Chiyoda-ku (JP)

Correspondence Address: CROWELL & MORING LLP;INTELLECTUAL PROPERTY GROUP, P.O. BOX 14300, WASHINGTON, DC, 20044-4300, US

(21) Appl. No.: 10/913,336

(22) Filed: Aug. 9, 2004

(30) Foreign Application Priority Data
Aug. 8, 2003 (JP) 2003-206653

(51) Int. Cl. H01L 21/4763; H01L 21/44; H01L 23/52; H01L 29/40

(52) U.S. Cl. 257/758; 438/687; 438/678; 438/622; 438/642; 257/762

(57) ABSTRACT

It is an object of the present invention to provide a semiconductor device production method in which an electroconductive capping (metal) layer is formed on a copper interconnect surface, wherein the capping (metal) layer is selectively formed to produce the semiconductor device of high reliability. In the semiconductor device production method, a capping (metal) layer is formed on a copper interconnect in a semiconductor integrated circuit, a first capping (metal) layer is formed by electroless plating with a plating solution containing a reducing agent active on a copper interconnect surface, and then a second capping (metal) layer is formed by another electroless plating.

### FIELD OF THE INVENTION

The present invention relates to a semiconductor device production method, more particularly a method for forming a capping (metal) layer.

### BACKGROUND OF THE INVENTION

Higher operating speed of devices for a semiconductor have been required to achieve higher degree of integration and higher performance, which has been promoting further miniaturization and layer multiplication of internal wiring of LSIs. The miniaturization and layer multiplication increase interconnect resistance and also inter-wiring capacitance, and affect signal transfer speed in the interconnects. The resulting signal transfer delay time limits operational speed of the device. Therefore, the operational speed has been improved by lowering dielectric constant of the interlayer dielectric film to control capacity between the interconnects, and decreasing resistance of the interconnect material to decrease interconnect resistance.

Consequently, attempts have been made to use copper having a low specific resistance of 1.7 μΩcm as an interconnect material and a porous, low-k material for the interlayer dielectric film. For forming copper interconnects, grooved interconnects formed by the dual damascene method have been attracting attention, because dry etching of copper is generally not easy. One of the methods for forming grooved interconnects provides grooves of desired shape beforehand in an interlayer dielectric film of silicon oxide, deposits an interconnect material in the grooves, and removes the surplus interconnect material by chemical mechanical polishing (hereinafter referred to as CMP).

Copper may react with, or diffuse into, the dielectric film 4. In order to secure interconnect reliability, therefore, it is necessary to provide the capping (metal) layer 8 or barrier film 3 between the copper interconnect 2 and dielectric film 4. The materials traditionally used for a copper diffusion barrier are metal nitrides, e.g., titanium, tantalum and tungsten nitride, and high-melting metals, e.g., tantalum, tungsten and alloy thereof, as the barrier film 3. On the other hand, the capping (metal) layer 8 to be provided on the copper interconnect 2 has been made of an electroconductive material, which can decrease its dielectric constant.

It is necessary for the capping (metal) layer 8 of an electroconductive material to be selectively deposited on the upper surface of the copper interconnect. Consequently, electroless plating has been studied to provide the capping (metal) layer 8.

U.S. Pat. No. 5,695,810 discloses formation of a cobalt-tungsten-phosphorus electroconductive film as a capping (metal) layer by electroless plating. Sodium hypophosphite is commonly used as a reducing agent for cobalt-tungsten-phosphorus electroless plating. It is known that the compound is unreactive with copper and cannot be directly plated on copper. Therefore, it is necessary to coat the copper interconnect with a seed layer of palladium or the like, before a cobalt-tungsten-phosphorus film is electrolessly plated thereon.

JP-A-2001-230220 discloses a substituted plating method for depositing palladium by dissolving copper. However, this method, which needs dissolution of copper as an interconnect material, may involve a problem of significant local corrosion of copper resulting from, e.g., excessive dissolution of the grain boundaries of the copper crystal to deteriorate connection reliability of the copper interconnect. Moreover, when a porous low-K dielectric film is used, a plating solution may penetrate into the pores to cause problems, e.g., separation of the plating nuclei there, which can prevent the sufficiently selective deposition. These problems may deteriorate insulation between the interconnects, which is required to form fine interconnects.

JP-A-2002-151518 discloses deposition of a cobalt-tungsten-boron film, which directly reacts with copper, by electroless plating while dispensing with palladium. This method, however, involves a problem that the capping (metal) layer is not deposited in places on the fine interconnect sections as the miniaturization proceeds. It involves another problem, when a capping (metal) layer is to be deposited on a semiconductor coated with a porous dielectric film, that the plating solution may penetrate into the porous film to deteriorate insulation between the interconnects, resulting from, e.g., deposition of the metal in the film (see FIGS. 5 and 6).

### SUMMARY OF THE INVENTION

As discussed above, the conventional electroless plating methods for depositing a capping (metal) layer involve problems related to selective deposition, e.g., the film may not be deposited to totally cover copper, or may be deposited on a dielectric film in addition to the interconnect (see FIG. 7), to deteriorate insulation reliability between the interconnects.

The present invention is developed to solve the problems involved in the conventional techniques. More specifically, it is an object of the present invention to provide a semiconductor device of high reliability by taking a step for preventing a plating solution from penetrating into the dielectric film before an electroconductive capping (metal) layer is deposited by electroless plating, and by selectively depositing the capping (metal) layer on the copper interconnect. It is another object of the present invention to provide a method for producing the same.

The method of the present invention produces a semiconductor device provided with a capping (metal) layer to cover a copper interconnect formed in a dielectric film, wherein the capping (metal) layer is formed by electroless plating in two stages, one of which is an electroless plating reacting only on the copper surface in the first stage and another of which is an electroless plating reacting on the copper and/or capping (metal) layer surface in the second stage.

The method of the present invention also produces the semiconductor device, wherein the porous dielectric film surface is made water-repellent for the portion which may come into contact with a plating solution, before the capping (metal) layer is deposited by electroless plating.

The semiconductor device of the present invention is provided with a capping (metal) layer to cover a copper interconnect formed in a dielectric film, and also with a barrier film covering the sides and bottom of the copper interconnect, wherein the capping (metal) layer comprises at least two layers of an electroconductive material.

The present invention adopts electroless plating to deposit an electroconductive capping (metal) layer on a copper interconnect, wherein the protective film is selectively deposited on the copper interconnect while preventing penetration of a plating solution into the dielectric film in which the copper interconnect is provided, to prevent deterioration of copper interconnect and device reliability.

Other objects, features and advantages of the invention will become apparent from the following description of the embodiments of the invention taken in conjunction with the accompanying drawings.

### BRIEF DESCRIPTION OF THE DRAWINGS

FIG. 1 is a cross-sectional view of one embodiment of the semiconductor device of the present invention.

FIG. 2 illustrates the semiconductor device production method of the present invention.

FIG. 3 is a cross-sectional view of the semiconductor device with a laminated interconnect layer.

FIG. 4 is a cross-sectional view of the semiconductor device with an etch stop layer.

FIG. 5 is a cross-sectional view of the semiconductor device with copper deposited within of the dielectric film.

FIG. 6 is a cross-sectional view of the semiconductor device with a short part between the interconnects.

FIG. 7 is a cross-sectional view of the semiconductor device with copper deposited on the dielectric film surface.

### DESCRIPTION OF THE REFERENCE NUMERALS AND SIGNS

1 Capping (metal) layer
2 Copper interconnect
3 Barrier film
4, 26 Dielectric film
5 Seed layer
6 Copper film
7 Wiring groove
9 Palladium layer
10 Connection hole
11 Wiring plug
13 Abnormally deposited part
14 Short part between interconnects
17 First etch stop layer
19 Second etch stop layer
21 Silicon nitride film
24 Hydrophobicized surface
25 Short part
101 First capping (metal) layer
102 Second capping (metal) layer

### DETAILED DESCRIPTION OF THE INVENTION

The preferred embodiments of the semiconductor device and semiconductor device production method of the present invention are described by referring to the drawings.

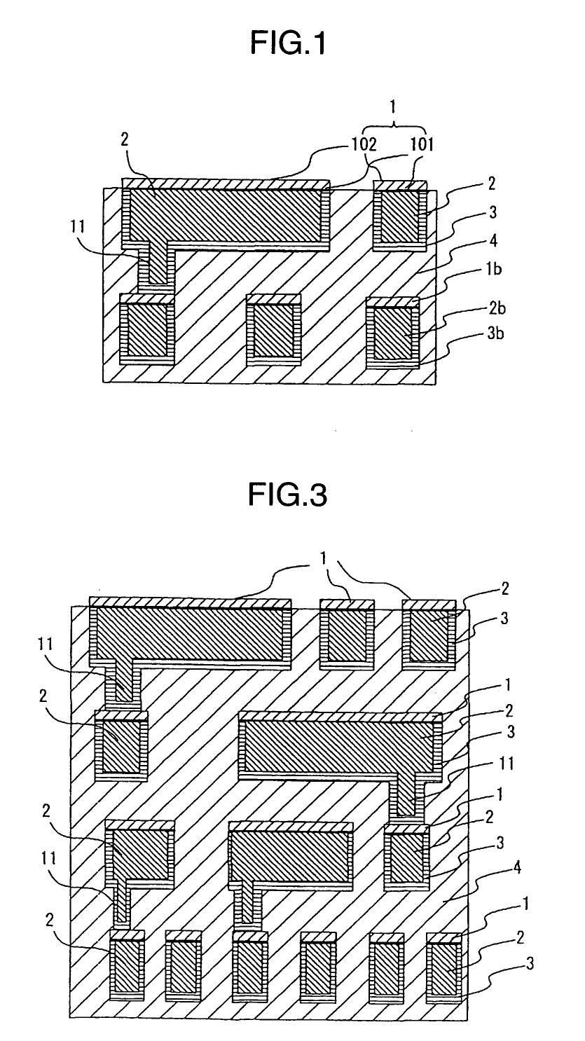

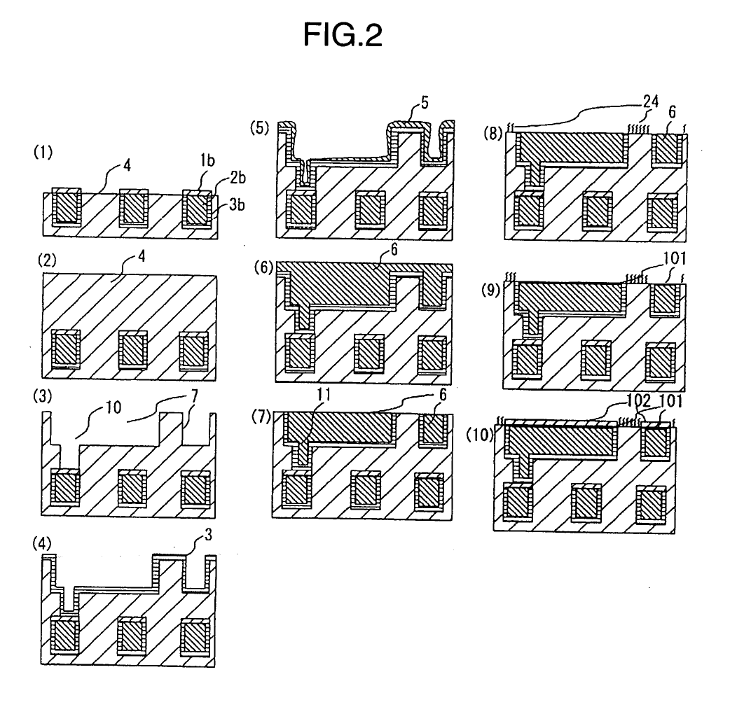

FIG. 1 is a cross-sectional view of one embodiment of the semiconductor device of the present invention. The semiconductor device of the present invention is produced basically by the following steps (see FIG. 2).
(A) Step for depositing the dielectric film 4 on a substrate working as a dielectric layer (in FIG. 2 (1), the lower copper interconnect 2b and capping (metal) layer 1b, described later, are already deposited, but the structure is not limited to this) (FIG. 2(2))
(B) Step for forming wiring grooves 7 and connection holes 10 in the dielectric film 4 (FIG. 2(3))
(C) Step for forming the barrier film 3 on the wiring groove 7 and connection hole 10 (FIG. 2(4))
(D) Step for forming the seed layer 5 on the barrier film 3 (FIG. 2(5))
(E) Step for depositing the copper 6 in the wiring groove 7 and connection hole 10 (FIG. 2(6))
(F) Step for removing the copper 6, formed into a film on the dielectric film 4, other than that on the wiring groove 7 and connection hole 10 parts, to form the copper interconnect 2 and wiring plug 11 (FIG. 2(7))
(G) Step for forming the hydrophobic surface 24 on the dielectric film 4 (FIG. 2(8))
(H) Step for forming the first capping (metal) layer 101 on the copper interconnect 2 (FIG. 2(9))
(I) Step for forming the second capping (metal) layer 102 on the first capping (metal) layer 101 (FIG. 2(10))

Steps (A) to (I) are repeated in a required number of cycles, to form a laminated interconnect layer (FIG. 3, four-layer structure in this case).

The dielectric film 4 may be inorganic or organic. The inorganic dielectric film is preferably of a compound having the siloxane bond, e.g., SiO₂, methyl siloxane, silsesquioxane hydride or methyl siloxane hydride. It can be formed by spraying or plasma-aided CVD. The organic dielectric film is of a hydrocarbon-based, low-k insulating material containing an aromatic ring. The commercial products useful for the film include Dow Chemical's “SILK” and “BCB”, Allied Signal's “FLARE”, and Schumacher's “VELOX”. These insulating materials are more preferably made porous, because decreased dielectric constant can be expected. The copper interconnect 2 can be formed electrical or electroless copper plating.

The barrier film 3 may be of a high-melting metal, e.g., titanium, tantalum, tungsten or alloy thereof, nitride, e.g., titanium, tantalum or tungsten nitride, or cobalt alloy, the film of which is produced by electroless plating.

The capping (metal) layer 1 is selectively deposited on the copper interconnect, as illustrated by the figures. The selective deposition is achieved by electroless plating. The method for producing the capping (metal) layer 1 is described.

In the porous dielectric film for the semiconductor device, the dielectric film surface is subjected to a hydrophobic treatment to form a hydrophobic surface 24. Next, the capping (metal) layer 101 is uniformly deposited on the surface 24 by electroless plating with a plating solution catalytically active on the copper surface and less active on the deposited metal (the solution is hereinafter referred to as the catalytic electroplating solution for undercoating) and then the capping (metal) layer 102 is deposited to a desired thickness by electroless plating with a plating solution active on the deposited metal (the solution is hereinafter referred to as the electroplating solution for thick film).

The dielectric film may be treated to have a hydrophobic surface with a known agent. The preferable agents include an alkyl silane coupling agent and surface treatment agent having a perfluoroalkyl group. The preferable catalytic electroplating solutions for undercoating include those containing an aldehyde, e.g., formaldehyde or glyoxylic acid, ascorbic acid, or borane complex, e.g., morpholine borane, as a reducing agent. The electroplating solution for thick film may be a known one having a gas barrier capacity. The one capable of forming a cobalt-tungsten-boron alloy is particularly preferable.

The capping (metal) layer 1 grows isotropically from the copper interconnect 2, by which is meant that it grows not only in the direction from the copper interconnect 2 upwards at a right angle but also in the direction from the copper interconnect 2 edge to the upper side of the barrier film 3 or further to the upper side of the dielectric film 4 by the distance same as thickness of the capping (metal) layer 1. It grows to the upper side of the barrier film 3 when the capping (metal) layer 1 is thinner than the barrier film 3, or to the upper side of the dielectric film 4 beyond the barrier film 3 when the capping (metal) layer 1 is thicker than the barrier film 3. Moreover, when the plating reaction on the surface of the barrier film 3 formed in Step (C) is active, the capping (metal) layer 1 extends isotropically from the barrier film 3 edge to the upper side of the dielectric film 4, as shown in FIG. 1. The isotropic growth of the capping (metal) layer 1 makes its edges not angular but round.

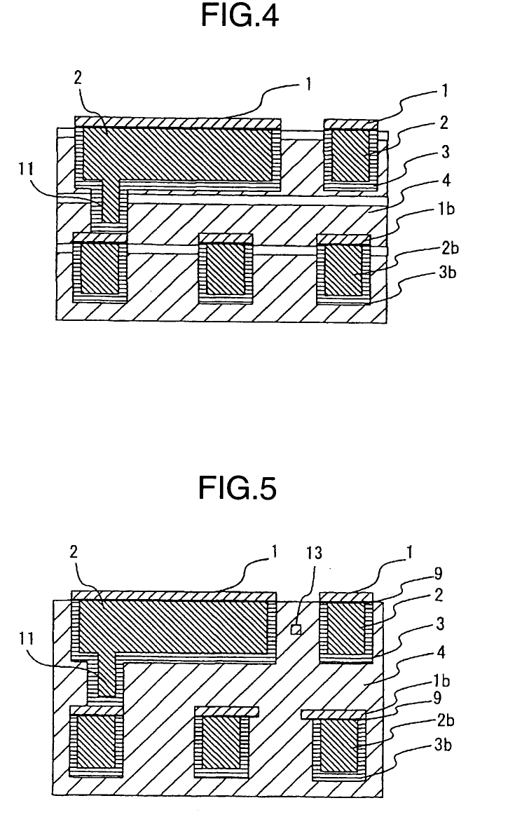

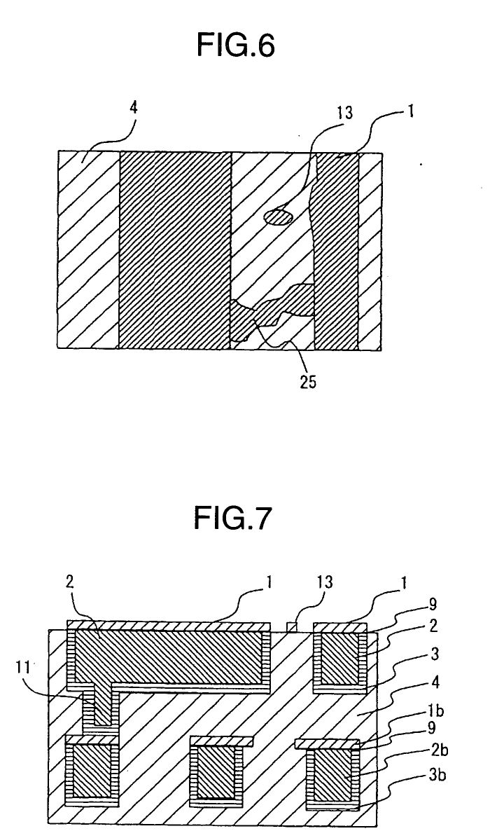

FIG. 4 is a cross-sectional view of one embodiment of the semiconductor device with an etch stop layer.

The semiconductor device illustrated in FIG. 4 is characterized by the dielectric layer being further provided with anther dielectric layer serving as the etch stop layers 17 and 19. These etch stop layers 17 and 19 provided all over the dielectric layer stop etching for chemical mechanical polishing or the like, to facilitate control of etching during the semiconductor device production process.

In this embodiment, the dielectric layer serving as the etch stop layer is provided between the layers where no capping (metal) layer is provided. However, it may be provided only on the interconnect layer.

### EXAMPLES

### Example 1

EXAMPLE 1 is described by referring to FIG. 2. A 200 mm-diameter silicon substrate was provided with the devices of the lower copper interconnect 2b (FIG. 2(1)), and then with the SiO₂ dielectric film 4 to a thickness of 1 μm by a known CVD procedure (FIG. 2(2)). The dielectric film was porous with a number of 3 nm-diameter holes. Then, the wiring grooves 7 and connection holes 10 were provided by dry etching (FIG. 2(3)), where the wiring groove was 0.3 μm wide and connection hole was 0.3 μm in diameter. Then, TA was formed into a 50 nm thick film by sputtering to serve as the barrier film 3 (FIG. 2(4)), and copper was formed into a 150 nm thick film to serve as the copper seed layer 5 (FIG. 2(5)). The copper seed layer 5 was formed by a long-distance, Cu-sputtering apparatus (Nippon Shinku Gijutsu, Co., Ltd., CERAUSZX-1000) at a film-making speed of 200 to 400 nm/minute. The coated substrate was immersed in the plating solution, described below, and plated under the conditions of solution temperature of 24° C., current density of 1 A/dm² and plating time of 5 minutes, to form the copper film 6 while depositing copper in the wiring grooves 7 and connection holes 10 (FIG. 2(6)), where phosphorus-containing copper was used for the anode.

| | | |
|---|---|---|
| Copper sulfate | 0.4 | mols/dm³ |
| Sulfuric acid | 2.0 | mols/dm³ |
| Chloride ion | 1.5 × 10⁻³ | mols/dm³ |
| MICROFAV CU2100 | 10 × 10⁻³ | dm³/dm³ (Copper |
| | | plating agent available |
| | | from Japan Electroplating |
| | | Engineers Co., Ltd.) |

Next, the coated substrate was treated by chemical mechanical polishing using a chemical mechanical polisher (IPEC's 472 type) with alumina-dispersed abrasive containing hydrogen peroxide at 1 to 2% and a pad (IC-1000 available from Rodel Corp.) at a polishing pressure of 190 G/cm². It was polished up to the barrier film 3, to form the copper interconnect 2 after removing an interconnect conductor (FIG. 2(7)).

Then, the dielectric film surface was treated to be hydrophobic, where it was immersed in a 3% by weight solution of octadecyltrimethoxy silane/ethanol for 5 minutes, dried at 120° C., and then washed in isopropyl alcohol for 1 minute.

Next, the coated substrate was further coated with the first capping (metal) layer 101, where it was immersed in the plating solution described below and treated under the conditions also described below for cobalt-based electroless plating (FIG. 2(9)). Then, the coated substrate was washed with pure water.

| | |
|---|---|
| Cobalt sulfate heptahydrate | 0.1 mols/dm³ |
| Citrate monohydrate | 0.3 mols/dm³ |
| Formaldehyde | 0.1 mols/dm³ |
| Polyethylene glycol | 0.05 g/dm³ |
| | (molecular weight: |
| | around 600) |
| Plating conditions | |
| pH | 12.5 (adjusted with |
| | an aqueous solution |
| | of tetramethyl |
| | ammonium hydroxide) |
| Solution temperature | 65° C. |
| Plating time | 7 minutes |

Next, the coated substrate was further coated with a second capping (metal) layer 102, where it was treated under the conditions described below for cobalt-based electroless plating and washed with pure water (FIG. 2(10)).

| | |
|---|---|
| Cobalt sulfate heptahydrate | 0.1 mols/dm³ |
| Citrate monohydrate | 0.3 mols/dm³ |
| Dimethylamine borane | 0.06 mols/dm³ |
| Tungstic acid | 0.03 mols/dm³ |
| RE610 | 0.05 g/dm³ (a |
| | surfactant available |
| | from Toho Chemical |
| | Industries Co., |
| | Ltd.) |
| Plating conditions | |
| pH | 9.5 (adjusted with |
| | an aqueous solution |
| | of tetramethyl |
| | ammonium hydroxide) |
| Solution temperature | 55° C. |
| Plating time | 3 minutes |

The semiconductor device thus prepared was processed by focused ion beams (FIB) to observe its cross-section including the wiring grooves 7 and connection holes 10 by a scanning electron microscope (hereinafter referred to as SEM). It was found that the copper interconnect 2 was coated with cobalt and cobalt-tungsten-boron alloy, uniformly deposited to form a 3 nm thick and 40 nm thick layer, respectively. Neither cobalt nor cobalt-tungsten-boron alloy were observed on the dielectric film surface or in the porous part in the dielectric film 4. The short-circuit test was carried out by applying a voltage between the interconnects. No short circuit was observed. The SEM analysis was conducted from the surface. No interconnect was found to have undeposited cobalt-tungsten-boron alloy. It was thus confirmed that the plating procedure adopted in EXAMPLE 1 provided the capping (metal) layers 1 selectively on the copper interconnect 2, causing no undeposition of the metals or deposition of the metals on any part other than the interconnect surface, like the one shown in FIG. 7 or the like.

The cobalt alloy formed an electrolessly plated film, composed of 79% of cobalt, 20% of tungsten and 1% of boron, all percentages by atom, as confirmed by Auger electron spectroscopy.

As discussed above, by the plating procedure adopted in EXAMPLE 1, cobalt and cobalt-tungsten-boron alloy are selectively formed as the capping (metal) layers 1 on the copper interconnect 2. These capping (metal) layers 1 prevented oxidation of the copper interconnect 2 and diffusion of copper from the copper interconnect 2 to the dielectric film 4 to control increase of the copper interconnect 2 resistance, making the semiconductor highly reliable.

### Examples 2 to 6, and Comparative Examples 1 to 2

In EXAMPLES 2 to 6, the dielectric substrate described in Table 1 was coated with the layers, where the combination of the plating pretreatment steps was changed to evaluate the selective deposition. The semiconductor was prepared in each of EXAMPLES following the procedure similar to that for EXAMPLE 1. The dielectric film 4 prepared in each of EXAMPLES 4 to 6 and COMPARATIVE EXAMPLE 1 was not porous. Selectivity was evaluated by SEM analysis and elementary analysis based on energy dispersion X-ray (EDX) spectroscopy according to the following patterns. Evaluation of undeposited part
100 holes, 0.12 μm in diameter, in a dot-shape pattern
   Abnormal Deposition on the Dielectric Film between the Interconnects
100 lines in a line-and-space pattern, 0.15 μm wide, where the dielectric film surface between the 2 lines was observed
   Abnormal Deposition in the Porous Dielectric Film
100 lines in a line-and-space pattern, 0.15 μm wide, where the dielectric film inside between the 2 lines was observed

In COMPARATIVE EXAMPLES 1 and 2, the respective porous substrate and SiO₂ dielectric substrate, also described in Table 1, were coated with the capping (metal) layer without having been pretreated for plating.

TABLE 1

| | | Plating pretreatment | | SEM analysis results | | |
|---|---|---|---|---|---|---|
| | | | Plating with | | | Deposition |
| | | | a catalytic | | | in the |
| | | Hydro- | electroplating | Undeposited | Deposition | dielectric |
| | Dielectric | phobicizing | solution for | parts | between interconnects | film |
| | substrate | treatment | undercoating | (number) | (number) | (number) |
| EXAMPLE 1 | Porous | Yes | Yes | 0 | 0 | 0 |
| | substrate | | | | | |
| EXAMPLE 2 | Porous | Yes | No | 10/100 | 0 | 0 |
| | substrate | | | | | |
| EXAMPLE 3 | Porous | No | Yes | 0 | 2/100 | 3/100 |
| | substrate | | | | | |
| COMPARATIVE | Porous | No | No | 12/100 | 25/100 | 30/100 |
| EXAMPLE 1 | substrate | | | | | |
| EXAMPLE 4 | SiO₂ | Yes | Yes | 0 | 0 | — |
| | substrate | | | | | |
| EXAMPLE 5 | SiO₂ | Yes | No | 8/100 | 0 | — |
| | substrate | | | | | |
| EXAMPLE 6 | SiO₂ | No | Yes | 0 | 10/100 | — |
| | substrate | | | | | |
| COMPARATIVE | SiO₂ | No | No | 12/100 | 12/100 | — |
| EXAMPLE 2 | substrate | | | | | |

These results indicate that hydrophobicizing the dielectric film surface as a plating pretreatment step can control penetration of the plating solution into the porous body and resulting abnormal deposition of the metals therein, and the abnormal deposition on the dielectric film surface. Moreover, plating with a catalytic electroplating solution for undercoating prevents undeposition on the cupper interconnect surface. Therefore, these results have confirmed the effect of the present invention of producing a copper interconnect and device of high reliability.

### Example 7

In EXAMPLE 7, the capping (metal) layer 1 was prepared in a manner similar to that for EXAMPLE 1, and evaluated by a life test. The semiconductor prepared in EXAMPLE 7 was provided with a 4-layered capping (metal) layer, as illustrated in FIG. 3, prepared by repeating cycles of the steps (1) to (10) shown in FIG. 2. The life test measured reliability of the dielectric film and interconnect resistance increase after 600 and 1200 hours of service. Interconnect shape
(A) Line width: 0.13 μm
(B) Film thickness: 0.8 μm
(C) Interconnect length: 2.5 mm
   Test Conditions
(A) Temperature: 175° C.
(B) Current density: 3×10⁶ A/cm²

Interconnect resistance increased by 2% after 600 hours and 5% after 1200 hours. No dielectric breakdown was observed after 1200 hours.

It was thus demonstrated that the semiconductor of this embodiment was stable over a long period of time. The reliability test with a voltage applied to the semiconductor also has confirmed the effect of the present invention of producing a copper interconnect and device of high reliability.

### Example 8

The semiconductor was prepared in EXAMPLE 8 in the same manner as in EXAMPLE 1, except that the dielectric film 26 was provided on the capping (metal) layer 1. The dielectric film 26 was of SiO₂, which was not porous. It was subjected to the life test, conducted in the same manner as in EXAMPLE 7.

Interconnect resistance increased by 2% after 600 hours and 4% after 1200 hours. No dielectric breakdown was observed after 1200 hours.

It was thus demonstrated that the semiconductor of this embodiment was stable over a long period of time. The reliability test with a voltage applied to the semiconductor also has confirmed the effect of the present invention of producing a copper interconnect and device of high reliability.

It should be further understood by those skilled in the art that although the foregoing description has been made on embodiments of the invention, the invention is not limited thereto and various changes and modifications may be made without departing from the spirit of the invention and the scope of the appended claims.

### ADVANTAGES OF THE INVENTION

The semiconductor production method of the present invention deposits a capping (metal) layer on a copper interconnect in a semiconductor, wherein the capping (metal) layer is deposited by electroless plating in 2 stages, with a plating solution active on the copper interconnect surface to form the first capping (metal) layer and then with another plating solution active on the copper and/or capping (metal) layer surface to form the second capping (metal) layer, to prevent undeposition of the capping (metal) layer thereby producing the copper interconnect and device of high reliability free of problems, e.g., oxidation of the copper interconnect resulting from the undeposition. The method of the present invention also treats the porous dielectric film to have a water-repellent surface for the portion which may come into contact with a plating solution to prevent penetration of the solution into the porous dielectric film and resulting abnormal deposition of the metals thereon, and also the abnormal deposition on the dielectric film between the interconnects before depositing the capping (metal) layer by electroless plating, in order to prevent short circuit between the interconnects and thereby to secure reliability of the copper interconnect and device.

Further, combining the above pretreatments enables the capping (metal) layer to be selectively formed only on the copper interconnect to provide a semiconductor device composed of highly reliable copper interconnect and device.

1. A method for producing a semiconductor device having a capping (metal) layer on a copper interconnect in a semiconductor integrated circuit, comprising the steps of:
forming a first capping (metal) layer by an electroless plating solution containing a reducing agent catalytically active on a copper interconnect surface, and then
forming a second capping (metal) layer by an electroless plating.

2. The semiconductor production method according to claim 1, wherein the first capping (metal) layer is formed by an electroless plating solution-containing cobalt.

3. The semiconductor production method according to claim 1, wherein the first capping (metal) layer is formed by an electroless plating solution containing a reducing agent active on the copper surface but inactive on the capping (metal) layer surface.

4. The semiconductor production method according to claim 1, wherein the second capping (metal) layer is formed by an electroless plating as a cobalt alloy film containing (1) cobalt, (2) at least one element selected from the group consisting of chromium, molybdenum, tungsten, rhenium, thallium and phosphorus, and (3) boron.

5. A method for producing a semiconductor device having a capping (metal) layer on a copper interconnect in a semiconductor integrated circuit, comprising the steps of:
subjecting a dielectric film surface to a hydrophobic treatment; and then
forming a capping (metal) layer on a copper interconnect by an electroless plating.

6. A method for producing a semiconductor device having a capping (metal) layer on a copper interconnect in a semiconductor integrated circuit, comprising the steps of:
subjecting a dielectric film surface to a hydrophobic treatment; then
forming a first capping (metal) layer by an electroless plating solution containing a reducing agent active on a copper interconnect surface, and then
forming a second capping (metal) layer by an electroless plating.

7. A semiconductor device provided with a capping (metal) layer on a copper interconnect in a semiconductor integrated circuit, wherein the capping (metal) layer comprises at least two layers of electroconductive material.

8. The semiconductor device with a capping (metal) layer on a copper interconnect in a semiconductor integrated circuit according to claim 7, wherein a first capping (metal) layer on a copper surface comprises cobalt.

9. The semiconductor device with a capping (metal) layer on a copper interconnect in a semiconductor integrated circuit according to claim 7, wherein a second capping (metal) layer on a copper surface comprises (1) cobalt, (2) tungsten and (3) boron.
